(19) United States
(12) Patent Application Publication
(10) Pub. No.: US 2021/0199727 A1
(43) Pub. Date: Jul. 1, 2021

(54) DISPLAY PANEL AND DISPLAY DEVICE

(71) Applicant: Shanghai Tianma AM-OLED Co.,Ltd., Shanghai (CN)

(72) Inventors: Zi XU, Shanghai (CN); Xinzhao LIU, Shanghai (CN); Lin CHENG, Shanghai (CN); Shuai YANG, Shanghai (CN)

(21) Appl. No.: 16/909,683

(22) Filed: Jun. 23, 2020

(30) Foreign Application Priority Data
Dec. 31, 2019 (CN) 201911418492.5

(51) Int. Cl. G01R 31/56; G09G 3/3225; G01R 31/26

(52) U.S. Cl. CPC G01R 31/56; G09G 2330/04; G01R 31/2621; G09G 3/3225

(57) ABSTRACT

A display panel and a display device are provided. The display panel includes a display unit; a visual test component including test signal input terminals; a driving chip including display signal input terminals; and a plurality of signal lines configured to generate driving signals for the display unit. In a visual test phase, the visual test component is configured to provide signals to signal lines through test signal input terminals. In a display phase, the driving chip is configured to provide signals to the signal lines through the display signal input terminals. The visual test component includes at least one first switch connected to at least one signal line. A control terminal of the at least one first switch is connected to the driving chip. In the visual test phase, the at least one first switch is turned on for connection under a control of the visual test component.

### CROSS-REFERENCES TO RELATED APPLICATIONS

This application claims priority of Chinese Patent Application No. 201911418492.5, filed on Dec. 31, 2019, the entire contents of which are hereby incorporated by reference.

### FIELD OF THE DISCLOSURE

The present disclosure generally relates to the field of display technology and, more particularly, relates to a display panel and a display device.

### BACKGROUND

With the continuous development of the display technologies, consumers' requirements for display panels are constantly increasing. Various types of display panels have emerged in a rapid succession, and have been developed rapidly, such as liquid crystal display panels, and organic light-emitting display panels, etc. Further, display technologies, such as 3D display, touch display, curved surface display, ultra-high-resolution display, and privacy display, continue to emerge to meet the consumers' demands.

Organic light-emitting display panels are widely favored by consumers because of their advantages, such as light weight, thinness, easy bending, high contrast, and low power consumption. The market shares of the organic light-emitting display panels in the display field have been increased year by year, and the organic light-emitting display panels are currently the most researched area in the field of display technologies. After the organic light-emitting display panels is shipped from the factory and before being bounded with the integrated circuits (ICs) to ensure the product quality, a visual test (VT) procedure is generally performed. In particular, signals are input through the VT signal terminals to make the display panel to display a pure color image or a checkerboard image to perform the VT. When the display panel is bound to the IC and enters the normal display phase, the VT signal terminals enter the idle state. However, when the IC inputs signals, the VT signal terminals also receive signals. When the display panel is tested at a high temperature and high humidity environment, the VT signal terminals are easily electrochemically eroded by water or oxygen in the environment. Accordingly, the reliability of the display panel is adversely affected.

Therefore, there is a need to avoid the electrochemical corrosion of the VT signal terminals and ensure the reliability of the display panel. The disclosed display panel and display device are directed to solve one or more problems set forth above and other problems in the art.

### BRIEF SUMMARY OF THE DISCLOSURE

One aspect of the present disclosure provides a display panel. The display panel may include a display unit; a visual test component including a plurality of test signal input terminals; a driving chip having a plurality of display signal input terminals; and a plurality of signal lines configured to generate driving signals for the display unit. In a visual test phase, the visual test component is configured to provide signals to the plurality of signal lines through the plurality of test signal input terminals. In a display phase, the driving chip is configured to provide signals to the plurality of signal lines through the plurality of display signal input terminals. The visual test component includes at least one firs switch connected to at least one signal line of the plurality of signal lines. A control terminal of the first switch is connected to the driving chip. In the visual test phase, the first switch is turned on for connection under a control of the visual test component; and in the display phase, the first switch is turned off for disconnection under a control of the driving chip.

Another aspect of the present disclosure provides another display panel. The display panel may include a display unit; a visual test component including a plurality of test signal input terminals; a driving chip including a plurality of display signal input terminals; and a plurality of signal lines configured to generate driving signals for the display unit. In a visual test unit, the visual component is configured to provide signals to the plurality of signal lines through the plurality of test signal input terminals. In a display phase, the driving chip is configured to provide signals for the plurality of signal line through the plurality of display signal input terminals. The visual test component includes a visual test unit, an electrostatic discharge unit, and at least one first switch connected to at least one signal line of the plurality of signal lines. The visual test unit includes the plurality of test signal input terminals. The electrostatic discharge unit is connected to the visual test unit through at a portion of the plurality of signal lines. A control terminal of the at least one first switch is connected to the driving chip; and in the display phase, the at least one first switch is turned off for disconnection under a control of the driving chip.

Other aspects of the present disclosure can be understood by those skilled in the art in light of the description, the claims, and the drawings of the present disclosure.

### BRIEF DESCRIPTION OF THE DRAWINGS

The following drawings are incorporated in and constitute a part of the specification, illustrating embodiments of the present disclosure, and together with the detailed descriptions serve to explain the mechanism of the present disclosure.

FIG. 1 illustrates an exemplary display panel consistent with various disclosed embodiments of the present disclosure;

FIG. 2 illustrates a zoomed-in view of the region A1 in FIG. 1 consistent with various disclosed embodiments of the present disclosure;

FIG. 3 illustrates a zoomed-in view of a portion of another exemplary display panel consistent with various disclosed embodiments of the present disclosure;

FIG. 4 illustrates a zoomed-in view of a portion of another exemplary display panel consistent with various disclosed embodiments of the present disclosure;

FIG. 5 illustrates a zoomed-in view of a portion of another exemplary display panel consistent with various disclosed embodiments of the present disclosure;

FIG. 6 illustrates a zoomed-in view of a portion of another exemplary display panel consistent with various disclosed embodiments of the present disclosure;

FIG. 7 illustrates a zoomed-in view of a portion of another exemplary display panel consistent with various disclosed embodiments of the present disclosure;

FIG. 8 illustrates a zoomed-in view of a portion of another exemplary display panel consistent with various disclosed embodiments of the present disclosure;

FIG. 9 illustrates a zoomed-in view of a portion of another exemplary display panel consistent with various disclosed embodiments of the present disclosure;

FIG. 10 illustrates a zoomed-in view of a portion of another exemplary display panel consistent with various disclosed embodiments of the present disclosure;

FIG. 11 illustrates an exemplary electrostatic discharge unit consistent with various disclosed embodiments of the present disclosure;

FIG. 12 illustrates another exemplary display panel consistent with various disclosed embodiments of the present disclosure;

FIG. 13 illustrates a zoomed-in view of the region A2 in FIG. 12 consistent with various disclosed embodiments of the present disclosure; and

FIG. 14 illustrates an exemplary display device consistent with various disclosed embodiments of the present disclosure.

### DETAILED DESCRIPTION

Reference will now be made in detail to exemplary embodiments of the disclosure, which are illustrated in the accompanying drawings. Hereinafter, embodiments consistent with the disclosure will be described with reference to drawings. Wherever possible, the same reference numbers will be used throughout the drawings to refer to the same or like parts. It is apparent that the described embodiments are some but not all the embodiments of the present disclosure. Based on the disclosed embodiments, persons of ordinary skill in the art may derive other embodiments consistent with the present disclosure, all of which are within the scope of the present disclosure. Further, in the present disclosure, the disclosed embodiments and the features of the disclosed embodiments may be combined when there are no conflicts.

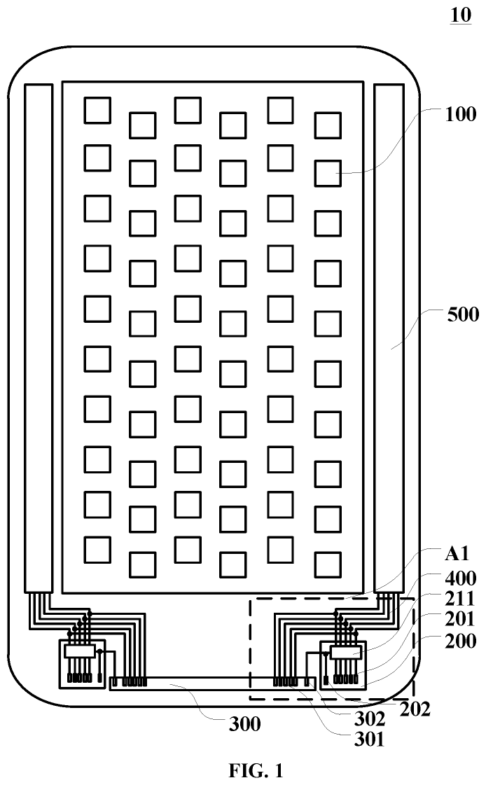

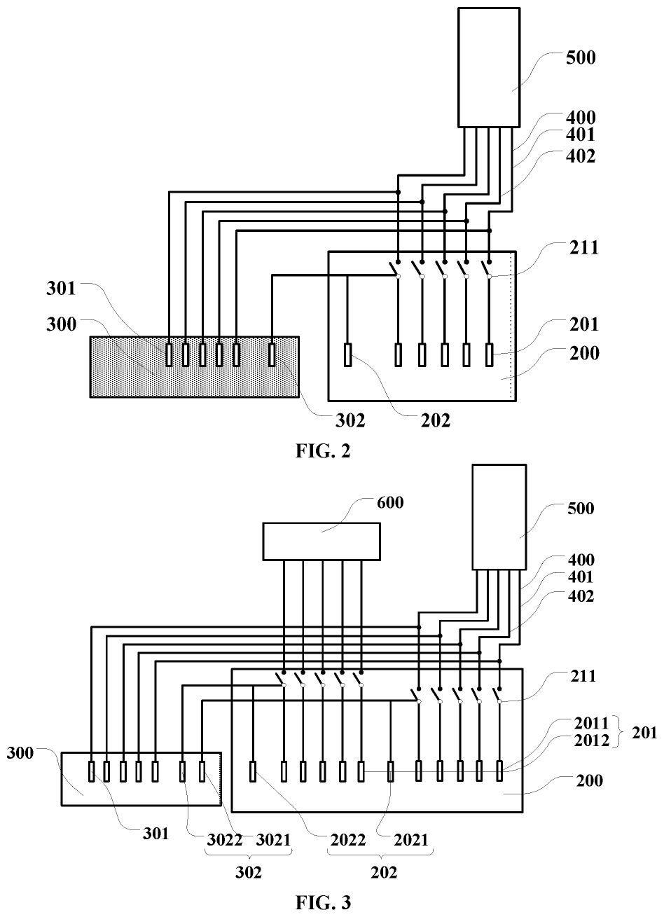

The present disclosure provides a display panel and a display device. FIG. 1 illustrates an exemplary display panel consistent with various disclosed embodiments of the present disclosure; and FIG. 2 illustrates a zoomed-in view of the region A1 in FIG. 1.

As shown in FIGS. 1-2, the display panel 10 may include a display unit 100, and a visual test component 200. The visual test component 200 may include a plurality of test signal input terminals 201. The display panel 10 may also include a driving chip 300. The driving chip 300 may include a plurality of display signal input terminals 301. Further, the display panel 10 may include a plurality of signal lines 400. The plurality of signal lines 400 may be configured to generate driving signals for the display unit 100. In the visual test phase, the visual test component 200 may be configured to provide signals to each of the plurality of the signal lines 400 through the plurality of test signal input terminals 201. In the display phase, the driving chip 300 may be configured to provide signals to each of the plurality of signal lines 400 through the plurality of display signal input terminals 301.

Further, the visual test component 200 may include at least one first switch 211 connected to at least one signal line 400 of the plurality of signal lines 400. The control terminal of the at least one first switch 211 may be connected to the driving chip 300. In the visual test phase, the at least one first switch 211 may be turned on for connection under the control of the visual test component 200. In the display phase, the at least one first switch 211 may be turned off for disconnection under the control of the driving chip 300.

The display panel 10 provided in the present disclosure may be an organic light-emitting display panel, a nano-light-emitting diode display panel, or other types of display panels, etc. The display unit 100 may include an anode and a cathode, and a light-emitting layer disposed between the anode and the cathode. The light-emitting layer may emit light when a voltage is applied between the anode and the cathode. The light-emitting layer may be an organic light-emitting layer, or a nano-light emitting diode layer, etc.

Further, in one embodiment, the visual test component 200 may include a control terminal 202. The control terminal of the first switch 211 may be connected to the control terminal 202 of the visual test component 200. In the visual test phase, the control terminal 202 may apply a signal to the control terminal of the first switch 211 to make the first switch 211 conductive (i.g., turn the first switch on). The driving chip 300 may also include a control terminal 302. The control terminal of the first switch 211 may be connected to the control terminal 302 of the driving chip 300. In the display phase, the control terminal 302 of the driving chip 300 may apply a signal to the control terminal of the first switch 211 to turn off the first switch 211.

For illustrative purposes, the number of structures such as the signal lines 400 and the first switches 211 is schematically shown in FIG. 1 and the following drawings. The number of the signal lines 400 and the first switches 211 is not limited by the present disclosure, and the specific number may be determined according to specific circumstances.

Thus, the display panel 10 provided by the present disclosure may include the visual test component 200 used in the visual test phase and the driving chip 300 used in the normal display phase, and the plurality of signal lines 400 for generating driving signals for the display unit 100. The plurality of signal lines 400 may be respectively connected to the visual test component 200 and the driving chip 300. Further, the visual test component 200 may include at least one first switch 211 connected to at least one signal line 400 of the plurality of signal lines 400. During the visual test phase, the first switches 211 may be turned on for connection under the control of the visual test component 200 during the visual test phase and, during the display phase, the first switches 211 may be turned off for disconnection under the control of the driving chip 300. Thus, the signals provided by the driving chip 300 on the plurality of signal lines 400 may be prevented from being transmitted to the visual test component 200 during the display phase. If the signals are transmitted on the visual test component 200, an electrochemical erosion issue may happen when the visual test component 200 is tested in the high-temperature and high-humidity environment of the display panel 10 because of the electric potential generated by the signals and the water vapor and oxygen in the environment. Accordingly, the configuration of the display panel 10 may avoid the erosion; and the reliability of the display panel 10 may be ensured.

In one embodiment, as shown in FIG. 1, the display panel 10 may include a driving circuit 500. The driving circuit 500 may include a gate driving circuit and/or a light-emitting driving circuit. The plurality of signal lines 400 may be connected to the driving circuit 500. The plurality of signal lines 400 may be connected to the gate driving circuit and/or the light-emitting driving circuit. The plurality of signal lines 400 may be configured to generate gate driving signals and/or light-emitting driving signals for the display unit 200. The plurality of signal lines 400 may include constant voltage signal lines, clock signal lines and trigger signal lines, etc. The constant voltage signal lines may include a first level signal line 401 and a second level signal line 402. The first level signal line 401 may be configured to transmit high-level signals, and the second level signal line 402 may be configured to transmit low-level signals. The clock signal lines may be configured to provide clock pulse signals for the driving circuit 500. The trigger signal lines may be configured to provide trigger signals to the driving circuit 500. Further, as shown in FIG. 1, the driving circuit 500 may be disposed at both sides of the display panel 10 and may provide driving signals to the display unit 100 from both sides. In some embodiments, the driving circuit 500 may be disposed at one side of the display panel 10 and may provide driving signals for the display unit 100 from one side.

The signal lines 400 for providing signals to the driving circuit 500 may be configured to transmit high-level signals, low-level signals, or pulse signals. If such signals are applied to the visual test component 200, the visual test component 200 and the water vapor or oxygen in the environment may easily have an electrochemical corrosion. The signal lines 400 may be connected to the visual test component 200 through the first switches 211, and the first switches 211 may be turned off during the display phase. Thus, the visual test component 200 may be prevented from being corroded during the display phase.

Further, in other embodiments, among the plurality of signal lines 400, besides the gate driving signal lines and/or the light-emitting driving signals of the display unit 100, the plurality of signal lines 400 may also include other signal lines. FIG. 3 illustrates a zoom-in view of a portion of an exemplary display panel consistent with various disclosed embodiments of the present disclosure.

As shown in FIG. 3, the display panel 10 may also include a plurality of short-circuit rods 600; and the plurality of signal lines 400 may also include signal lines connecting the visual test component 200 with the plurality of short-circuit rods 600. In the visual test phase, the signal lines may provide data signals and/or short-circuit control signals for the short-circuit rods 600. In the visual test phase, the plurality of short-circuit rods 600 may be configured to short-circuit different data lines together according to the signals provided by the visual test component 200. For example, the plurality of short-circuit rods may short-circuit the data lines of the display panels with the same light-emitting color such that the display panel 10 may display a pure color image. The signals provided by the visual test component 200 for the short-circuit rods 600 may include the data signals that provides a display element with gray scale signals and the short-circuit control signals for controlling the connection and disconnection between the data signals and the short-circuit rods 600. The data lines may be the data lines that provides the two types of signals described above, or the data lines that provides one of the two types of signals described above.

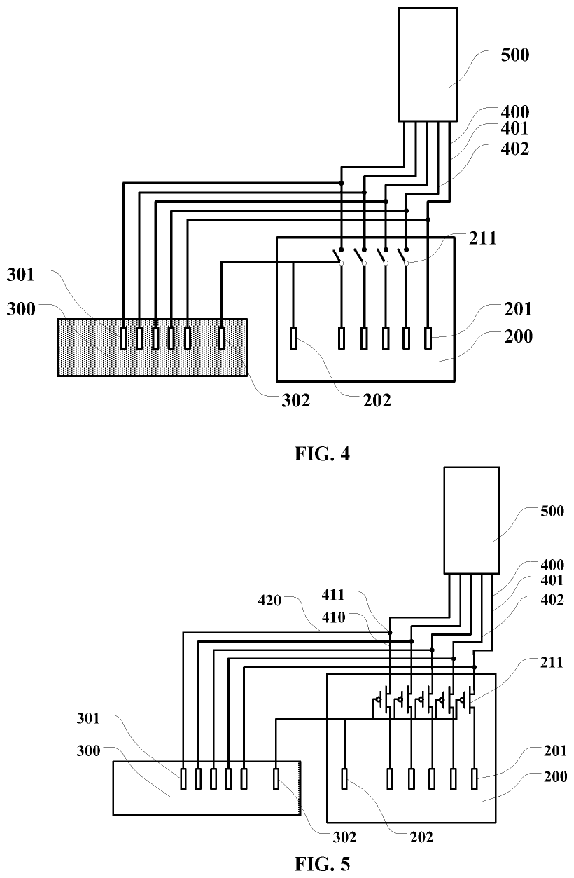

FIG. 4 illustrates a zoom-in view of a portion of another exemplary display panel consistent with various disclosed embodiments of the present disclosure. As shown in FIG. 4, among the plurality of signal lines 400, the first level signal line 401 may be directly connected to the visual test component 200 without being through the first switch 211, and the remaining signal lines 400 may be connected to the visual test component 200 through the first switches 211. When a high-level signal is applied to the signal line, it may be less susceptible to the corrosion, and when a low-level signal is applied to the signal line, it may be susceptible to the corrosion. Thus, in such a configuration, the first switch 211 may connect the signal lines 400 except the ones with the high-level signals to the visual test component 200 such that the visual test component 200 may be prevented from being eroded.

Further, in one embodiment, as shown in FIG. 2 or FIG. 3, the plurality of signal lines 400 may be connected to the visual test component 200 through the first switches 211. In such a configuration, the visual test component 200 may be prevented from receiving the signals of any signal line 400 during the display phase. Thus, the visual test component 200 may be ensured not to be corroded.

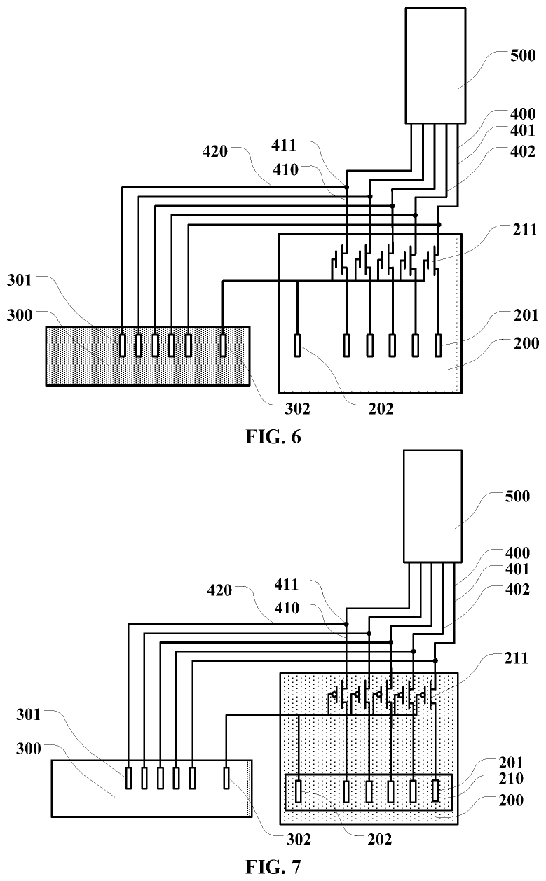

FIG. 5 illustrates a zoomed-in view of a portion of another exemplary display panel consistent with various disclosed embodiments of the present disclosure. FIG. 6 illustrates a zoomed-in view of a portion of another exemplary display panel consistent with various disclosed embodiments of the present disclosure. In such display panels, the first switches may be thin film transistors.

As shown in FIG. 5, the thin film transistors may be PMOS transistors. The visual test component 200 may be configured to provide low-level signals to the gates of the thin film transistors during the visual test phase. The driving chip 300 may be configured to provide high-level signals to the gates of thin film transistors during the display phase.

As shown in FIG. 6, the thin film transistors may be NMOS transistors. The visual test component 200 may be configured to provide high-level signals to the gates of the thin film transistors during the visual test phase. The driving chip 300 may be configured to provide low-level signals to the gates of the thin film transistors during the display phase.

The configurations in FIG. 5 and FIG. 6 may enable the first switches 211 to be turned on during the visual test phase and to be turned off during the display phase. Thus, it may ensure that the visual test component is not subject to corrosion during the display phase.

Further, as shown in FIG. 5 and FIG. 6, in one embodiment, the plurality of signal lines 400 each may include a first node 411, and each signal line 400 may be divided into a first sub-signal line 410 and a second sub-signal line 420 after being through the first node 411. The first sub-signal line 410 may be connected to the vision test component 200, and the second sub-signal line 420 may be connected to the driving chip 300. In the visual test phase, the visual test component 200 may transmit signals to the first node 411 through the first sub-signal line 410, and then transmit the signals to the driving circuit 500 through the signal line 400. In the display phase, the driving chip 300 may transmit signals to the first node 411 through the second sub-signal line 420 and transmit the signals to the driving circuit 500 through the signal line 400. The first sub-signal line 410 and the second sub-signal line 420 may allow the signal lines to transmit the signals during the visual test stage and the display stage, respectively. Thus, interference may not occur.

FIG. 7 illustrates a zoomed-in view of a portion of another exemplary display panel consistent with various disclosed embodiment of the present disclosure. As shown in FIG. 7, in one embodiment, the visual test component 200 may include a visual test unit 210. The visual test unit 210 may include a plurality of test signal input terminals 201. The first switches 211 may be located between the first nodes 411 and the visual test unit 210. When the first switch 211 is located between the first node 411 and the visual test unit 210, when the first switches 211 are turned off for disconnection in the display phase, the signals on the signal lines 400 may not be transmitted to the visual test unit 210. Thus, the corrosion of the visual test unit 210 may be avoided. Further, in one embodiment, as shown in FIG. 7, the visual test unit 210 may also include a control terminal 202 connected to the first switch 211.

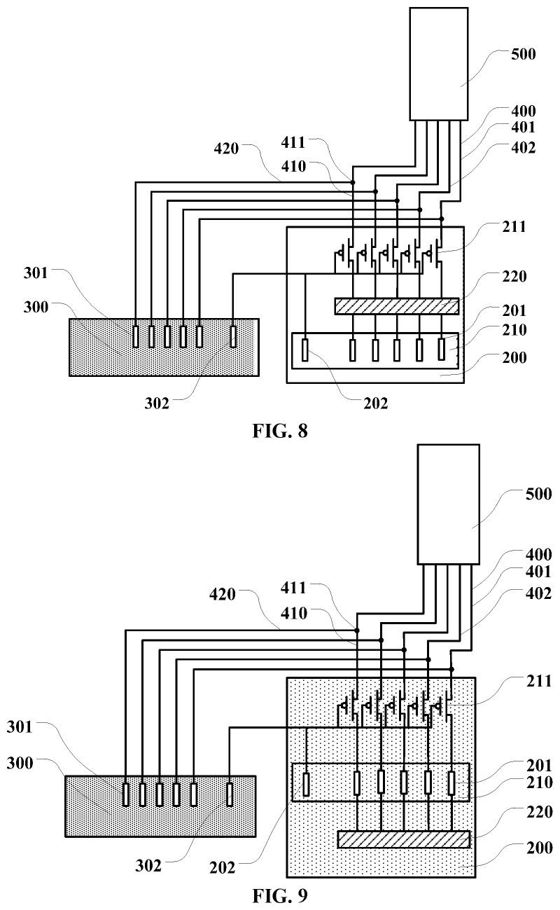

FIG. 8 illustrates a zoomed-in view of a portion of another exemplary display panel consistent with various disclosed embodiments of the present disclosure. As shown in FIG. 8, in one embodiment, the visual test component 200 may further include an electrostatic discharge unit 220. The electrostatic discharge unit 220 may be connected to the visual test unit 210 through at least a portion (a certain number) of the plurality of signal lines 400. In such a display panel, because electrical signals are applied to the signal lines, it is easy to generate static electricity. To ensure the normal use of the signal lines, the signal lines may be connected to the electrostatic discharge unit such that when the static electricity is generated, they may be discharged in time to avoid the damage to the signal lines by the static electricity. In one embodiment, the electrostatic discharge unit 220 may be connected to the visual test unit 210 through at least a portion of the signal lines of the plurality of signal lines 400, and the static electricity generated on the visual test unit 210 in the visual test phase may be discharged through the electrostatic discharge unit 220.

Optionally, in one embodiment, as shown in FIG. 8, the first switches 211 may be disposed between the first nodes 411 and the electrostatic discharge unit 220, and the electrostatic discharge unit 220 may be disposed between the first switches 211 and the visual test unit 210. Thus, during the display phase, when the first switches 211 are turned off for disconnection, the visual test unit 210 and the electrostatic discharge unit 220 may be both disconnected from the signal lines 400 such that the erosion of the visual test unit 210 and the electrostatic discharge unit 220 may be avoided during the display phase.

FIG. 9 illustrates a zoomed-in view of another exemplary display panel consistent with various disclosed embodiments of the present disclosure. As shown FIG. 9, in one embodiment, the first switches 211 may be disposed between the first nodes 411 and the visual test unit 210, and the visual test unit 210 may be disposed between the first switches 211 and the electrostatic discharge unit 220. In such a configuration, when the first switches 211 are turned off, both the visual test unit 210 and the electrostatic discharge unit 220 may be disconnected from the signal lines 400. Thus, the corrosion of the visual test unit 210 and the electrostatic discharge unit 220 may be avoided during the display phase.

Optionally, in one embodiment, as shown in FIG. 8 and FIG. 9, the visual test unit 210 and the electrostatic discharge unit 220 may be directly connected through the signal lines 400. In such a configuration, the static electricity on the visual test unit 210 may be ensured to be discharged through the electrostatic discharge unit 220.

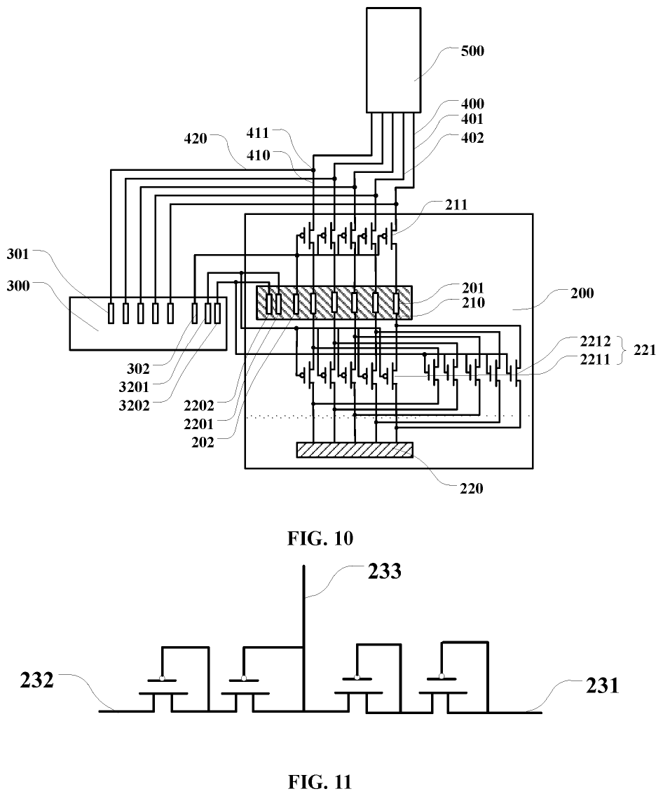

FIG. 10 illustrates a zoom-in view of anther exemplary display panel consistent with various disclosed embodiments of the present disclosure. As shown in FIG. 10, the visual test component 200 may further include a plurality of second switches 221 connected to at least one signal line 400. The second switches 221 may be disposed between the visual test unit 210 and the electrostatic discharge unit 220. The control terminal of the second switch 221 may be connected to the visual test unit 210 and the driving chip 300 at the same time. The second switch 221 may be turned off under the control of the driving chip 300. Such a configuration may ensure that the electrostatic discharge unit 220 may not be corroded during the display phase.

Optionally, in some embodiments, during the visual test phase, the second switches 221 may be turned on under the control of the visual test unit 210. In such a configuration, the static electricity on the visual test unit 210 may be timely discharged by the electrostatic discharge unit 220 in the visual test phase. In other embodiments, during the visual test phase, the second switches 221 may be turned off under the control of the visual test unit 210. In such a configuration, in the visual test phase, if the signals on the visual test unit 210 are normal signals, the visual test unit 210 and the electrostatic discharge unit 220 may not be conductive, and the visual test unit 210 may still work normally. When abnormal static electricity appears on the visual test unit 210, the abnormal static electricity may switch the second switch on such that the abnormal static electricity may be timely discharged from the electrostatic discharge unit 220. The process for the abnormal static electricity turning the second switches 221 on will be described later.

Further, referring to FIG. 10, in one embodiment, the second switch 221 may include a first sub-switch 2211 and a second sub-switch 2212, and each signal line 400 may be connected to the electrostatic discharge unit 220 through the first sub-switch 2211 and the second sub-switch 2212 at the same time. The first sub-switch 2211 may be a PMOS thin film transistor, and the second sub-switch 2212 may be an NMOS thin film transistor.

Optionally, in the visual test phase, the first sub-switch 2211 and the second sub-switch 2212 may be turned off under the control of the visual test unit 210. When high-level signals generated on the signal line 400 turn on the first sub-switch 2211, the high-level signals may be transmitted to the electrostatic discharge unit 220 through the first sub-switch 2211 for discharging. When low-level signals generated on the signal line 400 turns on the second sub-switch 2212, the low-level signals may be transmitted to the electrostatic discharge unit 220 through the second sub-switch 2212 for discharging.

The visual test unit 210 may further include a control terminal 2201 and a control terminal 2202. The driving chip 300 may further include a control terminal 3201 and a control terminal 3202. The control terminal 2201 of the visual test unit 210 and the control terminal 3201 of the driving chip may be connected to the control terminal of the first switch 2211 to control the first switch 2211. The control terminal 2201 of the visual test unit 210 and the control terminal 3202 of the driving chip 300 may be connect to the second switch 2212 to control the second switch 2212.

In such a configuration, the first sub-switch 2211 and the second sub-switch 2212 may be provided. Thus, no matter whether in the display phase or the visual test phase, when abnormal static electricity is generated on the signal lines 400, whether the abnormal static electricity is high or low, all may be released in time by the electrostatic discharge unit 400. Further, since the first sub-switch 2211 and the second sub-switch 2212 may be both at an “off” state during the display phase, it may be ensured that the electrostatic discharge unit 220 may be prevented from being corroded in the display phase.

Optionally, in one embodiment, the electrostatic discharge unit 220 may include a ground terminal, and the second switch may be connected to the ground terminal. The electrostatic discharge unit 220 may conduct the static electricity to the ground terminal and may timely discharge abnormal static electricity on the visual test unit.

FIG. 11 illustrates an exemplary electrostatic discharge unit consistent with various disclosed embodiments of the present disclosure. As shown in FIG. 11, the electrostatic discharge unit 220 may further include a plurality of electrostatic discharge circuits 230. The electrostatic discharge circuit 230 may include a signal connection terminal 233, a high-level discharge terminal 231, and a low-level discharge terminal 232. The signal connection terminal 233 may be configured to connect the signal lines 400. The high-level discharge terminal 231 may be connected to a first level signal line 410 through a thin film transistor and the low-level discharge terminal 232 may be connected to a second level signal line 420 through a thin film transistor.

The thin film transistor in the electrostatic discharge circuit 230 may be a PMOS thin film transistor. The source of the thin film transistor of the high-level discharge terminal 231 may be connected to the signal connection terminal 233, and the gate and the drain of the thin film transistor of the high-level discharge terminal 231 may be connected to the first level signal line 410. The gate and the source of the thin film transistor of the low-level discharge terminal 232 may be connected to the signal connection terminal 233, and the drain of the thin film transistor of the low-level discharge terminal 232 may be connected to the second level signal line 420.

Further, the thin film transistor in the electrostatic discharge circuit 230 may be an NMOS thin film transistor. The gate and the source of the thin film transistor of the high-level discharge terminal 231 may be connected to the signal connection terminal 233, and the drain of the thin film transistor of the high-level discharge terminal 231 may be connected to the first level signal line 410. The source of the thin film transistor of the low-level discharge terminal 232 may be connected to the signal connection terminal 233, and the gate and the drain of the thin film transistor of the high-level discharge terminal 231 may be connected to the first-level signal line 420. Such a configuration may enable the high-level static electricity generated on the visual test unit 210 to be timely conducted into the first level signal line 410 through the electrostatic discharge circuit 230, and the low-level static electricity may be timely conducted to the second level signal line 420 through the electrostatic discharge circuit 230.

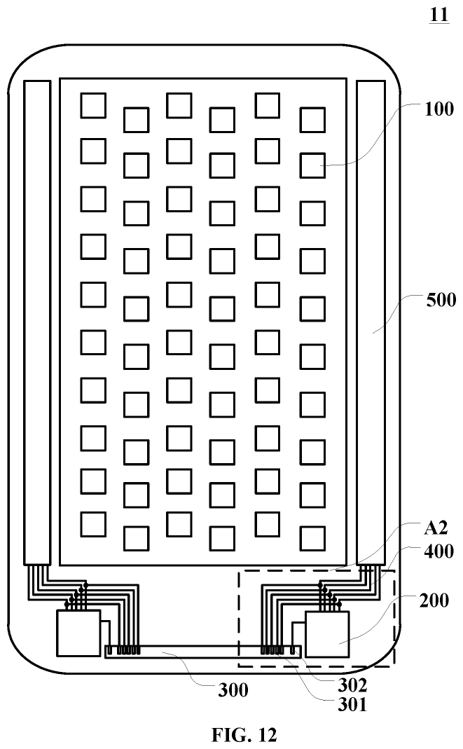

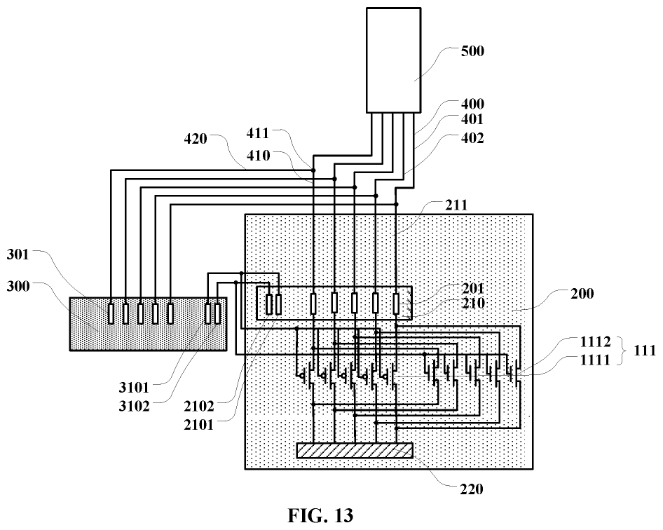

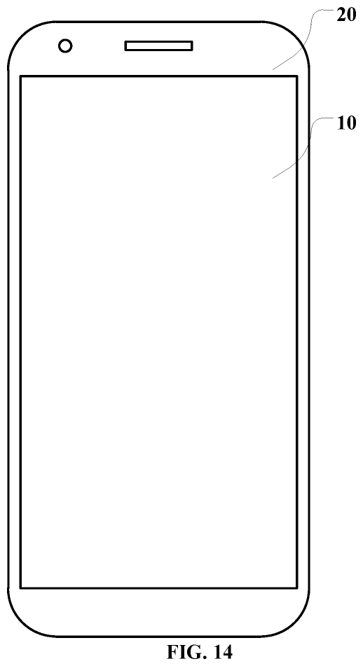

The present disclosure also provides another display panel. FIG. 12 illustrates an exemplary display panel consistent with various disclosed embodiments of the present disclosure; and FIG. 13 illustrates a zoomed-in view of the region A2 in FIG. 12.

As shown in FIGS. 12-13, the display panel 11 may include a display unit 100 and a visual test component 200. The visual test component 200 may include a plurality of test signal input terminals 201. The display panel 11 may also include a driving chip 300. The driving chip 300 may include a plurality of display signal input terminals 301. Further, the display panel 11 may include a plurality of signal lines 400. The plurality of signal lines 400 may be used to generate driving signals for the display unit 100. In the visual test phase, the visual test component 200 may provide signals to each signal line 400 through the plurality of test signal input terminals 201. In the display phase, the driving chip 300 may provide signals to each signal line 400 through the plurality of display signal input terminals 301.

The visual test component 200 may include a visual test unit 210 and an electrostatic discharge unit 220, and at least one first switch 111 connected to at least one signal line 400. The visual test unit 210 may include a plurality of test signal input terminals 201. The electrostatic discharge unit 220 may be connected to the visual test unit 210 through at least a portion of the plurality of signal lines 400. The control terminals of the first switches 111 may be connected to both the visual test component 200 and the driving chip 300. In the display phase, the first switches 111 may be turned off under the control of the driving chip 300.

The present disclosed display panel 11 may include the visual test component 200 used in the visual test phase and the driving chip 300 used in the normal display phase, and the plurality of signal lines 400 used for generating driving signals for the display unit 100 of the display panel 11. The plurality of signal lines 400 may be connected to the vision test component 200 and the driving chip 300, respectively. The visual test component 200 may include the visual test unit 210 and the electrostatic discharge unit 220, and at least one first switch 111 connected to at least one signal line 400 of the plurality of signal lines 400. During the display phase, the first switch 111 may be turned off under the control of the driving chip 300. Thus, the signals provided by the driving chip 300 on the plurality of signal lines 400 may be prevented from being transmitted to the visual test component 200 during the display phase. Accordingly, the electrochemical corrosion of the visual test component 200 due to the potential generated by the signals and the water or oxygen in the environment when the experiment is performed in the high temperature and high humidity environment may be avoided. Thus, the reliability of the display panel 11 may be ensured.

Further, the display panel 11 provided in the present disclosure may be an organic light-emitting display panel, a nano-light-emitting diode display panel, or other types of display panels, etc. In addition, the plurality of signal lines 400 may be used to generate gate driving signals and/or light-emitting control signals for the display unit 100, and may also be used to connect with short-circuit rods to provide data signals or short-circuit control signals to the display unit 100.

In one embodiment, during the visual test phase, the first switches 111 may be turned on under the control of the visual test unit 210. In such a configuration, the static electricity on the visual test unit 210 may be timely discharged through the electrostatic discharge unit 200 during the visual test phase. In some embodiments, during the visual test phase, the second switches 111 may be turned off under the control of the visual test unit 210. In such a configuration, if the signals on the visual test unit 210 are normal signals during the visual test phase, the visual test unit 210 and the electrostatic discharge unit 220 may not be electrically connected, and the visual test unit 210 may still work normally. When the abnormal static electricity occurs on the visual test unit 210, the abnormal static electricity may switch the first switches 111 on such that the abnormal static electricity may be timely discharged through the electrostatic discharge unit 220. The process for the abnormal static electricity to turn on the first switches 111 is described later.

FIG. 13 illustrates a zoomed-in view of the region A2 in FIG. 12 consistent with various disclosed embodiments of the present disclosure. As shown in FIG. 13, each signal line 400 may include a first node 411, and each signal line 400 may be divided into a first sub-signal line 410 and a second sub-signal line 420 after passing through the first node 411. The first sub-signal line 410 may be connected to the vision test component 200, and the second sub-signal line 420 may be connected to the driving chip 300. The visual test unit 210 may be disposed between the first node 411 and the first switch 111, and the first switch 111 may be disposed between the visual test unit 210 and the electrostatic discharge unit 220. In such a configuration, it may ensure that the electrostatic discharge unit 220 is prevented from being corroded during the display stage.

Further, in one embodiment, as shown in FIG. 13, the first switch 111 may include a third sub-switch 1111 and a fourth sub-switch 1112, and each signal line 400 may be connected to the electrostatic discharge unit 220 through the third sub-switch 1111 and the fourth sub-switch 1112. The third sub-switch 1111 may be a PMOS thin film transistor, and the fourth sub-switch 1112 may be an NMOS thin film transistor.

In the visual test phase, the third sub-switch 1111 and the fourth sub-switch 1112 may be turned off under the control of the visual test unit 210. When high-level signals generated on the signal line 400 turn the third sub-switch 1111 on, the high-level signals may be transmitted to the electrostatic discharge unit 220 through the third sub-switch 1111 for discharging. When low-level signals generated on the signal line 400 turn the fourth sub-switch 1112 on, the low-level signals may be transmitted to the electrostatic discharge unit 220 through the fourth sub-switch 1112 to discharge.

In such a configuration, the third sub-switch 1111 and the fourth sub-switch 1112 may be provided such that no matter whether it is a display phase or a visual test phase, when abnormal static electricity is generated on the signal line 400, whether the abnormal static electricity is high or low, all can be discharged in time by the electrostatic discharge unit 400. Further, since the first sub-switch 1111 and the second sub-switch 1112 may be both in an “off” state during the display phase, the electrostatic discharge unit 220 in the display phase may be ensured to avoid being corroded.

Optionally, in one embodiment, the electrostatic discharge unit 220 may include a ground terminal, and the second switch may be connected to the ground terminal. The electrostatic discharge unit 220 may conduct the static electricity to the ground terminal and may timely discharge the abnormal static electricity on the visual test unit.

The present disclosure also provides a display device. FIG. 14 illustrates an exemplary display device consistent with various disclosed embodiments of the present disclosure.

As shown in FIG. 20, the display device 20 may include a display panel. The display panel may be the display panel 10 or the display panel 11 described in the previous embodiments, or other appropriate display panel. The display device 20 may be a mobile phone, a folding display screen, a notebook computer, a television, a watch, or a smart wearable display device, etc.

Thus, in the disclosed display panel and display device, first switches may be disposed between the visual test component and the signal lines. In the display phase, the first switches may be disconnected under the control of the driving chip such that the devices in the visual test component may be prevented from being corroded during the display stage. Thus, the reliability of the display panel may be ensured.

The description of the disclosed embodiments is provided to illustrate the present disclosure to those skilled in the art. Various modifications to these embodiments will be readily apparent to those skilled in the art, and the generic principles defined herein may be applied to other embodiments without departing from the spirit or scope of the disclosure. Thus, the present disclosure is not intended to be limited to the embodiments shown herein but is to be accorded the widest scope consistent with the principles and novel features disclosed herein.

What is claimed is:

1. A display panel, comprising:
a display unit;
a visual test component, including a plurality of test signal input terminals;
a driving chip, including a plurality of display signal input terminals; and
a plurality of signal lines, configured to generate driving signals for the display unit,
wherein:
in a visual test phase, the visual test component is configured to provide signals to the plurality of signal lines through the plurality of test signal input terminals;
in a display phase, the driving chip is configured to provide signals to the plurality of signal lines through the plurality of display signal input terminals;
the visual test component includes at least one first switch connected to at least one signal line of the plurality of signal lines;
a control terminal of the at least one first switch is connected to the driving chip;
in the visual test phase, the at least one first switch is turned on for connection under a control of the visual test component; and
in the display phase, the at least one first switch is turned off for disconnection under a control of the driving chip.

2. The display panel according to claim 1, wherein:
the plurality of signal lines are configured to transmit gate driving signals and/or light-emitting driving signals for the display unit;
the plurality of signal lines include constant-voltage signal lines, pulse signal lines and trigger signal lines;
the constant-voltage signal lines include a first level signal line and a second level signal line;
the first level signal line is configured to transmit high-level signals; and
the second level signal line is configured to transmit low-level signals.

3. The display panel according to claim 2, wherein:
the display panel further includes a plurality of short-circuit rods;
the plurality of signal lines also include signal lines configured to connect the visual test component with the plurality of short-circuit rods; and
in the visual test phase, the signal lines provide data signals and/or short-circuit signals for the plurality of short-circuit rods.

4. The display panel according to claim 2, wherein:
the first level signal line in the plurality of signal lines is directly connected to the visual test component without being through the at least one first switch; and
remaining signal lines of the plurality signal lines except the first level signal line are connected to the visual test component through the at least one first switch.

5. The display panel according to claim 2, wherein:
all the plurality of signal lines are connected to the visual test component through the at least one first switch.

6. The display panel according to claim, wherein:
the at least one first switch is a thin film transistor,
wherein:
when the thin film transistor is a PMOS transistor, the visual test component is configured to provide low-level signals to a gate of the thin film transistor in the visual phase and provide high-level signals to the gate of the thin film transistor in the display phase; and
when the thin film transistor is an NMOS transistor, the visual test component is configured to provide high-level signals to a gate of the thin film transistor in the visual phase and provide low-level signals to the gate of the thin film transistor in the display phase

7. The display panel according to claim 1, wherein:
each signal line of the plurality of signal lines includes a first node;
each signal line of the plurality signal lines is divided into a first sub-signal line and a second sub-signal line after passing through the first node;
the first sub-signal line is connected to the visual test component; and
the second sub-signal line is connected to the driving chip.

8. The display panel according to claim 7, wherein:
the visual test component includes a visual test unit;
the visual test unit includes the plurality of test signal input terminals; and
the at least one first switch is disposed between first node and the visual test component.

9. The display panel according to claim 7, wherein:
the visual test component also includes an electrostatic discharge unit; and
the electrostatic discharge unit is connected to the visual test component through at least a portion of the plurality of signal lines.

10. The display panel according to claim 9, wherein:
the at least one first switch is disposed between the first node and the electrostatic discharge unit; and
the electrostatic discharge unit is disposed between the at least one first switch and the visual test component.

11. The display panel according to claim 9, wherein:
the at least one first switch is disposed between the first node and the visual test component; and
the visual test component is disposed between the at least one first switch and the electrostatic discharge component.

12. The display panel according to claim 11, wherein:
the visual test component further includes a second switch connected to at least one signal line of the plurality of signal lines;
the second switch is disposed between the visual test component and the electrostatic discharge unit;
a control terminal of the second switch is connected to the driving chip; and
in the display phase, the second switch is turned off for disconnection under the control of the driving chip.

13. The display panel according to claim 12, wherein:
in the visual test phase, the second switch is turn on/off under the control of the visual test unit.

14. The display panel according to claim 12, wherein:
the second switch includes a first sub-switch and a second sub-switch;
each signal line of the plurality of signal lines is connected to the electrostatic discharge unit through each of the first sub-switch and the second sub-switch;
the first sub-switch is a PMOS thin film transistor; and
the second sub-switch is an NMOS thin film transistor.

15. The display panel according to claim 14, wherein:
in the visual test phase, the first sub-switch and the second sub-switch are turned off for disconnection under the control of the visual test unit;
when high-level signals are generated on the signal line and turn the first sub-switch on for connection, the high level-signals are transmitted to the electrostatic discharge unit through the first sub-switch to discharge; and
when low-level signals are generated on the signal line and turn the second sub-switch on for connection, the low level-signals are transmitted to the electrostatic discharge unit through the second sub-switch to discharge.

16. The display panel according to claim 15, wherein:
the electrostatic discharge unit includes a ground terminal; and
the second switch is connected to the ground terminal.

17. A display panel, comprising:
a display unit;
a visual test component, including a plurality of test signal input terminals;
a driving chip, including a plurality of display signal input terminals; and
a plurality of signal lines, configured to generate driving signals for the display unit,
wherein:
in a visual test phase, the visual component is configured to provide signals for the plurality of signal lines through the plurality of test signal input terminals;
in a display phase, the driving chip is configured to provide signals for the plurality of signal lines through the plurality of display signal input terminals;
the visual test component includes a visual test unit, an electrostatic discharge unit, and at least one first switch connected to at least one signal line of the plurality of signal lines;
the visual test unit includes the plurality of test signal input terminals;
the electrostatic discharge unit is connected to the visual test unit through at least a portion of the plurality of signal lines;
a control terminal of the at least one first switch is connected to the driving chip; and
in the display phase, the at least one first switch is turned off for disconnection under a control of the driving chip.

18. The display panel according to claim 17, wherein:
each signal line of the plurality of signal lines includes a first node;
each signal line of the plurality of signal lines is divided into a first sub-signal line and a second sub-signal line after passing through the first node;
the first sub-signal line is connected to the visual test component;
the second sub-signal line is connected to the driving chip;
the visual test unit is disposed between the first node and the at least one first switch; and
the at least one first switch is disposed between the visual test unit and the electrostatic discharge unit.

19. The display panel according to claim 18, wherein:
the at least one first switch includes a third sub-switch and a fourth sub-switch;
each signal line of the plurality of signal lines is connected to the electrostatic discharge unit through both the third sub-switch and the fourth sub-switch;
the third sub-switch is a PMOS transistor; and
the fourth sub-switch is an NMOS transistor.

20. The display panel according to claim 19, wherein:
in the visual test phase, the third sub-switch and the fourth sub-switch are turned off under a control of the visual test component;
when high-level signals generated on the signal line turn the third sub-switch on, the high-level signals are transmitted to the electrostatic discharge unit to discharge; and
when low-level signals generated on the signal line turn the fourth sub-switch on, the low-level signals are transmitted to the electrostatic discharge unit to discharge.
